(19) United States
(12) Patent Application Publication
(10) Pub. No.: US 2002/0157058 A1
(43) Pub. Date: Oct. 24, 2002

(54) System and method for feedback-based unequal error protection coding

(75) Inventors: Meir Ariel, Tel Aviv (IL); Jacob Goldberger, Givatayim (IL); Ofer Amrani, Tel Aviv (IL)

Correspondence Address: G.E. EHRLICH (1995) LTD., c/o ANTHONY CASTORINA, SUITE 207, 2001 JEFFERSON DAVIS HIGHWAY, ARLINGTON, VA, 22202, US

(73) Assignee: Cute Ltd.

(21) Appl. No.: 09/785,489

(22) Filed: Feb. 20, 2001

(51) Int. Cl. H03M 13/00

(52) U.S. Cl. 714/774; 714/790

(57) ABSTRACT

A decoding device for receiving a data stream from a data source over a noisy channel, the data being arranged in variable length packets using unequal encoding levels for different parts of the data stream, the decoder having a feedback transmitter for sending feedback data via a feedback channel to said data source to indicate a level of quality of data receipt at said decoder, thereby to provide adaptive error correction and concealment in a data stream transferred over said channel.

### FIELD OF THE INVENTION

The present invention relates to a system and method for System for feedback-based unequal error protection coding in media communications.

### BACKGROUND OF THE INVENTION

The problem of error concealment in video communications is becoming increasingly important because of the growing interest in the delivery of compressed video over wireless channels. Several packet-oriented transmission modes have been proposed for next generation wireless standards like EGPRS (Enhanced General Packet Radio Service) or UMTS (Universal Mobile Telecommunications System), which are mostly based on the same principle: Long message blocks, typically IP packets that enter the wireless part of the network, are split up into segments of desired length, which can be multiplexed onto link layer packets of fixed size. The packets are then transmitted sequentially over the wireless link, reassembled, and passed on to the next network element. However, compared to the rather benign channel characteristics of present day fixed or wire line networks, wireless links suffer from severe fading, noise, and interference conditions in general, thus resulting in a relatively high residual bit error rate after detection and decoding. By use of efficient cyclic redundancy check (CRC) mechanisms, resulting bit errors are generally detected with very high probability, and every corrupted segment, i.e. a segment which contains at least one erroneous bit, is discarded to prevent error propagation through the network. But if only one single segment is missing at the reassembly stage, the upper layers packet cannot be reconstructed anymore. The result is a significant increase in packet loss rate at higher levels. The effect of such information loss can be devastating since any damage to the compressed bit stream may lead to objectionable visual distortion at the decoder. More importantly, even a small number of erroneous bits can lead to catastrophic error propagation, i.e., to desynchronization of the coded information such that many following bits are undecodable until synchronization is reestablished. Moreover, sometimes the decoded information is still useless even after synchronization is obtained, since there is no way to determine which spatial or temporal locations correspond to the decoded data. It is therefore vitally necessary to keep packet loss within a certain acceptable range depending on the individual quality-of-service (QoS) requirements. However, due to the delay constraints typically imposed by most audio or video codecs, the use of automatic repeat request (ARQ) schemes is often prohibited both at link level and at transport level. In addition, retransmission strategies cannot be applied to any broadcast or multicast scenarios. Thus, forward error correction (FEC) strategies have to be considered, which provide a simple means to reconstruct the content of lost packets at the receiver from the redundancy that has been spread out over a certain number of subsequent packets.

FEC coding is a well-known technique for achieving error correction and detection in data communications. FEC has the disadvantage of increasing transmission overhead and hence reducing usable bandwidth for the payload data. Thus it is generally used judiciously in video services, since video services are very demanding in bandwidth but can tolerate a certain degree of loss.

FEC has been employed for error recovery in video communications in several standards. In H.261, an 18-bit error-correction code is computed and appended to 493 video bits for detection and correction of random bit errors in integrated services digital network (ISDN). For packet video, it is much more difficult to apply error correction because several hundred bits have to be recovered when a packet loss occurs. Lee et al. (S. H. Lee, P. J. Lee, and R. Arsari, “Cell loss detection and recovery in variable rate video,” in Proc. 3rd Int. Workshop Packet Video, Morriston, March 1990, the contents of which are hereby incorporated by reference) propose to combine Reed-Solomon (RS) codes with block interleaving to recover lost ATM cells. An RS (32,28,5) code is applied to every block of 28 bytes of data to form a block of 32 bytes. After applying the RS code row by row in the memory up to the forty-seventh row, the payload of 32 ATM cells is formed by reading column by column from the memory with the attachment of one byte indicating the sequence number. In this way, detected cell loss at the decoder corresponds to one byte erasure in each row of 32 bytes after de-interleaving. Up to four lost cells out of 32 cells can be recovered.

The Grand-Alliance High-Definition Television broadcast system has adopted a similar technique for combating transmission errors (K. Challapali, X. Lebegue, J. S. Lim, W. H. Paik, R. Saint Girons, E. Petajan, V. Sathe, P. A. Snopko, and J. Zdepski, “The grand alliance system for US HDTV,” Proc. IEEE, vol. 83, pp. 158-174, Feb. 1995, the contents of which are hereby incorporated by reference). In addition to using the RS code, data randomization and interleaving are employed to provide further protection. As a fixed amount of video data has to be accumulated to perform the block interleaving described above, relatively long delay is however introduced. To reduce the interleaving delay, a diagonal interleaving method has been proposed by Cochennec (J. -Y. Cochennec, “Method for the correction of cell losses for low bit-rate signals transport with the AAL type 1,” ITU-T SG15 Doc. AVC-538, July 1993, the contents of which are hereby incorporated by reference). At the encoder side, input data are stored horizontally in a designated memory section, which are then read out diagonally to form ATM cells. In the decoder, the data are stored diagonally in the memory and are read out horizontally. In this way, the delay due to interleaving is halved.

The use of FEC for MPEG-2 in a wireless ATM local-area network has been studied by Ayanoglu et al. (E. Ayanoglu, R. Pancha, and A. R. Reibman, and S. Talwar, “Forward error control for MPEG-2 video transport in a wireless ATM LAN,” ACM/Baltzer Mobile Networks Applicat., vol. 1, no. 3, pp. 245-258, Dec. 1996, the contents of which are hereby incorporated by reference). FEC is used at the byte level for random bit error correction and at the ATM cell level for cell-loss recovery. Such use of FEC techniques may be applied to both single-layer and two-layer MPEG data. It is shown that the two-layer coder outperforms the one-layer approach significantly, at a fairly small overhead. The paper also compares direct cell-level coding with the cell-level interleaving followed by FEC. It is noted that the paper concludes that the latter introduces longer delay and bigger overhead for equivalent error-recovery performance and suggests that direct cell-level correction is preferred.

Many formats used for transmitting data provide for retransmission in the case of irrecoverable data loss. However, certain data is often required to be used in real time at the receiving end and thus retransmission is unhelpful as the retransmitted data generally arrives too late. A payload format for generic FEC of media encapsulated in Real Time Protocol (RTP) which does not permit retransmission has been proposed by Rosenberg et al (J. Rosenberg and H. Schulzrinne, “An RTP payload format for generic error correction,” RFC 2733, December 1999, the contents of which are hereby incorporated by reference) based on exclusive-or (xor) operation as follows:

The sender takes a set of packets from the media stream, and applies an xor operation across the payloads. The sender also applies the xor operation over components of the RTP headers. Based on the procedures defined in the above-mentioned citation an RTP packet containing FEC information is produced. Such a packet can be used at the receiver to recover any one of the packets used to generate the FEC packet. Use of differing sets results in a tradeoff between overhead, delay, and recoverability. The payload format contains information that allows the sender to tell the receiver exactly which media packets have been used to generate the FEC. Specifically, each FEC packet contains a bitmask, called the offset mask, containing 24 bits. If bit i in the mask is set to 1, it may be concluded that the media packet with sequence number N+i has been used to generate the corresponding FEC packet. N is called the sequence number base, and is incorporated into the FEC packet as well. The offset mask and payload type are sufficient to signal arbitrary parity based FEC schemes with little overhead. As the sender generates FEC packets, they are sent to the receivers. The sender still usually sends the original media stream, as if there were no FEC. Such a procedure allows the media stream to be used by receivers which are not FEC capable.

Some FEC codes, referred to as non-systematic codes, do not require the original media to be sent; as the FEC stream is sufficient for recovery. Such FEC codes have the drawback, however, that all receivers must be FEC capable.

Returning to systematic codes and the FEC packets are not sent in the same RTP stream as the media packets, but rather as a separate stream, or as a secondary codec in the redundant codec payload format. When sent as a separate stream, the FEC packets have their own sequence number space. At the receiver, the FEC and original media are received. If no media packets are lost, the FEC can be ignored. In the event of loss, the FEC packets can be combined with other media and FEC packets that have been received, resulting in recovery of missing media packets. The recovery is exact; the payload is perfectly reconstructed, along with most components of the header. RTP packets which contain data formatted according to such a specification (i.e., FEC packets) are signaled using dynamic RTP payload types.

In greater detail, the xor-based FEC technique presented in RFC2733 uses a function f(x,y, . . . ) defined as the xor operator applied to the packets x,y, . . . . The output of this function is another packet, called the parity packet. For simplicity, we assume here that the parity packet is computed as the bitwise xor of the input packets. Recovery of data packets using parity codes is accomplished by generating one or more parity packets over a group of data packets. Four exemplary schemes are given as follows:

Scheme No. 1:

A parity code that generates a single parity packet over two data packets is selected. If the original media packets are a,b,c,d, the packet stream generated by the sender is of the form:

| | | | | |
|---|---|---|---|---|
| a | b | c | d | <-- media stream |
| | f(a,b) | | f(c,d) | <-- FEC stream |

where time increases to the right In the present scheme, the error correction code introduces a 50% overhead. If packet b is lost, a and f(a,b) may be used to recover b.

Scheme No. 2

Scheme no. 2 is similar to Scheme no. 1. However, instead of sending packet b followed by the packet formed by f(a,b), f(a,b) is sent before b. Such an order inversion requires additional delay at the sender but has the advantage that it allows certain bursts of two consecutive packet losses to be recovered. The packet stream generated by the sender is of the form:

| | | | | | |
|---|---|---|---|---|---|
| a | b | c | d | e | <-- media stream |
| f(a,b) | | f(b,c) | f(c,d) | f(d,e) | <-- FEC stream |

Scheme No. 3

It is not strictly necessary for the original media stream to be transmitted. In scheme no. 3, only non-systematic FEC packets are transmitted. Scheme no. 3 permits recovery of all single packet losses and some consecutive packet losses using slightly less overhead than scheme no. 2. The packet stream generated by the sender is of the form:

f(a,b) f(a,c) f(ab ,c) f(c,d) f(c,e) f(c,d,e)←FEC stream

Scheme No. 4

Scheme no. 4 again sends the original media stream but requires the receiver to wait an additional four packet intervals to recover the original media packets. It can recover from one, two or three consecutive packet losses. The packet stream generated by the sender is of the form:

| | | | | |
|---|---|---|---|---|
| a | b c | | d | <-- media stream |
| | f(a,b,c) | f(a,c,d) | f(a,b,d) | <-- FEC stream |

In addition to forward error correction, passive error concealment is known. In the case of MPEG video, the objective of passive concealment techniques is to estimate missing macroblocks and motion vectors. The underlying idea is that there is still enough redundancy in the sequence to be exploited by the concealment technique. Passive concealment techniques are used as part of postprocessing methods which utilize spatial data, or temporal data, or a hybrid of both (see, e.g., the papers by M. Wada, “Selective recovery of video packet loss using error concealment,” IEEE J Select. Areas Commun., vol. 7, pp. 807-814, June 1989, and J. Y. Park, M. H. Lee, and K. J. Lee, “A simple concealment for ATM bursty cell loss,” IEEE Trans. Consumer Electron., vol. 39, pp. 704-710, August 1993 the contents of which are hereby incorporated by reference). In such concealment methods, the aim of which is to hide the fact that erazure has taken place, missing macroblocks can be reconstructed by estimating their low-frequency DCT coefficients from the DCT coefficients of the neighboring macroblocks (see, e.g., Y. Wang, Q. Zhu, and L. Shaw, “Maximally smooth image recovery in transform coding,” IEEE Trans. Commun., vol. 41, pp. 1544-1551, October 1993, and Q. Zhu, Y. Wang, and L. Shaw, “Coding and cell loss recovery in DCT based packet video,” IEEE Trans. Circuits Syst. Video Technol., vol. 3, pp. 248-258, June 1993, the contents of which are hereby incorporated by reference), by estimating missing edges in each block from edges in the surrounding blocks as proposed by W. Kwok and H. Sun, “Multidirectional interpolation for spatial error concealment,” IEEE Trans. Consumer Electron., vol. 3, pp. 455-460, August 1993, or by the method of projections onto convex sets as described by H. Sun and W. Kwok in their paper “Concealment of damaged block transform coded images using projections onto convex sets,” IEEE Trans. Image Processing, vol. 4, pp. 470-477, April 1995—the contents of which are hereby incorporated by reference. An alternative to using spatial data for error concealment is to use motion compensated concealment whereby the average of the motion vectors of neighboring macroblocks is used to perform concealment (see M. Wada, “Selective recovery of video packet loss using error concealment,” IEEE J. Select. Areas Commun., vol. 7, pp. 807-814, June 1989—the contents of which are hereby incorporated by reference).

Decoding of the data in any of the above schemes is often carried out using trellis decoding. Trellis decoding builds up possible data paths, taking advantage of redundancy introduced by the use of a codebook, and then eliminates paths on the basis of a Hamming distance or Euclidian distance from the received bit stream. In other words a received data path, possibly containing errors, is corrected to the nearest of a series of possible data paths. Generally, the trellis decoder is able to produce a single unambiguous selection as its output but as the noise level increases, the likelihood increases of there being two or more data paths having equal minimum Hamming distance and which consequently cannot be discrimated between by the decoder. Such a noise level sets a limit on the usefulness of the Viterbi decoder.

### SUMMARY OF THE INVENTION

It is an object of the present invention to extend the usefulness of the Viterbi decoder to overcome the current limits on its usefulness.

According to a first aspect of the present invention there is thus provided a decoding device for receiving a data stream from a data source over a noisy channel, the data being arranged in variable length packets using unequal encoding levels for different parts of the data stream, the decoder having a feedback transmitter for sending feedback data via a feedback channel to said data source to indicate a level of quality of data receipt at said decoder, thereby to provide dynamic adaptation to conditions in said channel.

A preferred embodiment is operable to decode data encoded using RSC encoding.

Preferably, the data stream comprises data bits in a utilization order and interleaved parity bits, in a succession of data packets. The device preferably comprises:

a data receiver for receiving said data stream,

a data receiver for deinterleaving said data bits,

a parity bit retriever for retrieving and deinterleaving said parity bits from said data stream, and

a decoder for decoding said data bits with said deinterleaved parity bits, thereby to reconstruct data erased by said channel.

Preferably, said data packets comprise a plurality of fields of differing importance and wherein said data stream comprises unequal levels of error protection encoding to said fields, said feedback transmitter being operable to signal to said data source to increase said unequal levels of protection in the event of an increase in channel noise and to decrease said unequal levels of protection in the event of a decrease in said channel noise.

Preferably, said data packets comprise video data compressed using a transform combined with motion vectors of identified macroblocks.

Preferably, parameters of at least one of said unequal error protection encoding levels and said puncture matrix are obtained from a packet header.

Preferably, said header comprises an index defining a combination of unequal error protection encoding level and a puncture matrix in said packet header.

According to a second aspect of the present invention there is provided an encoding and transmitting device for encoding a data stream and transmitting said data stream over a noisy channel to a receiver device, the encoder having:

at least one encoder for encoding said data,

a packetizer for arranging the encoded data into variable length encoded packets using unequal encoding levels for different parts of the packet,

a feedback receiver for receiving feedback data via a feedback channel from said receiving device to indicate a level of quality of data receipt at said receiving device, and

an adapter for utilizing said feedback data to modify parameters used in said encoder, thereby to provide adaptive error correction and concealment in a data stream transferred over said channel.

Preferably, said data packets comprise a plurality of fields of differing importance and wherein said encoder is operable to apply unequal levels of error protection encoding to said fields.

Preferably, said encoder is operable to apply said unequal levels of error protection encoding via a puncture matrix.

Preferably, said encoder is operable to produce parity bits with a recursive systematic convolutional encoding process using parameters selectable in response to said feedback data.

Preferably, said recursive systematic convolutional encoding process is defined by

G=(1+D)/(1+D+D²),

where D indicates a once delayed prior input and D² indicates a twice delayed prior input.

Alternatively, said recursive systematic convolutional encoding process is defined by

G=(1+D+D⁴+D⁵+D⁶)/(1+D+D²+D⁴+D),

where D indicates a once delayed prior input, D² indicates a twice delayed prior input, D⁴ indicates a four times delayed prior input, D⁵ indicates a five times delayed prior input, and D⁶ indicates a six times delayed prior input.

Preferably, said encoder is operable to apply said unequal levels of error protection encoding via a puncture matrix, said puncture matrix being selectable according to said feedback data.

Preferably, said data packets comprise a plurality of fields of differing importance and wherein said encoder is operable to apply unequal levels of error protection encoding to said fields, according to parameters selectable according in accordance with said feedback data.

Preferably, said encoder further comprises a data interleaver, being operable to interleave said data in accordance with a uniformity criterion and wherein said uniformity criterion is selected such as to allow reconstruction of erased data packets from surviving data packets, whenever said erased data packets do not exceed a predetermined proportion of said surviving data packets.

Preferably, said uniformity criterion is such that for any window over a length w of said interleaved data, the proportion of data bits from any given packet remains substantially constant.

Preferably, parameters of at least one of said unequal error protection encoding levels and said puncture matrix is included in a packet header and are variable in accordance with said feedback data.

An embodiment of the invention is selectably operable to use any selected one of only a predetermined set of combinations of puncture matrices and differential encoding levels, which selection is influenced by said feedback data and which is operable to include an index of said selected combination in a packet header.

In a particularly preferred embodiment there are provided not just a single encoder but rather a plurality of encoders each for encoding using different encoding parameters, and an encoder selector for selecting one of said plurality of encoders based on said feedback data.

According to a further aspect of the present invention there is provided a system for streaming data and corresponding protective parity bits in packets over a channel, the system comprising

a recursive systematic convolutional encoder at a sending end for producing said corresponding protective parity bits,

a recursive systematic convolutional decoder at a receiving end for reconstructing data lost in the channel, and

a feedback channel between said sending end and said receiving end for allowing encoding parameters at said sending end to be modified by receiving conditions at said receiving end.

Preferably, said data packets comprise a plurality of fields of differing importance and wherein said encoder is operable to apply unequal levels of error protection encoding to said fields using parameters variable in accordance with feedback from said feedback channel.

Preferably, the system is operable to apply said unequal levels of error protection encoding via a puncture matrix, and wherein said puncture matrix is variable in accordance with feedback from said feedback channel.

Preferably, parameters of at least one of said unequal error protection encoding levels and said puncture matrix are variable in accordance with feedback from said feedback channel and are included in a packet header.

Preferably, said encoder is operable to use any selected one of only a predetermined set of combinations of puncture matrices and unequal error protection encoding levels, said selection being at least partially dependent on feedback from said feedback channel and which encoder is operable to include an index of said selected combination in a packet header.

Preferably, said channel includes a cellular connection.

Preferably, said data comprises compressed video.

Preferably, said compressed video comprises motion vector portions and transformed portions.

Preferably, method of transferring compressed multimedia data arranged into fields of varying importance over a channel liable to erasure in variable length packets, the method comprising:

inserting said data into said packets,

interleaving said data using a uniformity criterion,

generating parity bits using a recursive systematic convolutional code from said interleaved data according to parameters,

distributing said parity bits across said packets amongst said data,

transferring said packets over said channel,

reconstructing said compressed multimedia data at a receiver,

feeding back receipt conditions at said receiver back across said channel, and

modifying said parameters in accordance with said feedback, thereby to dynamically adapt encoding of said data stream to said channel conditions.

### BRIEF DESCRIPTION OF THE DRAWINGS

For a better understanding of the invention and to show how the same may be carried into effect, reference will now be made, purely by way of example, to the accompanying drawings.

With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice. In the accompanying drawings:

FIG. 1 is a generalized diagram of a video packet, showing typical packet fields for the MPEG-4 protocol.

FIG. 2 is a simplified diagram of an RSC encoder for use with embodiments of the present invention,

FIG. 3 is a simplified block diagram which shows a transmission path for a data stream according to an embodiment of the present invention,

FIG. 4 is a simplified block diagram showing the datastream protection encoder of FIG. 3 in greater detail,

FIG. 5 is a simplified block diagram showing the datastream protection decoder of FIG. 3 in greater detail,

FIG. 6 is a trellis diagram showing windowing of the trellis to eliminate data paths, and

FIG. 7 is a simplified block diagram showing a communication system according to a preferred embodiment of the present invention with a feedback channel between the decoder and the encoder.

### DESCRIPTION OF THE PREFERRED EMBODIMENTS

Before explaining at least one embodiment of the invention in detail, it is to be understood that the invention is not limited in its application to the details of construction and the arrangement of the components set forth in the following description or illustrated in the drawings. The invention is applicable to other embodiments or of being practiced or carried out in various ways. Also, it is to be understood that the phraseology and terminology employed herein is for the purpose of description and should not be regarded as limiting.

Reference is now made to FIG. 1, which is a simplified diagram showing a standard MPEG-4 data packet for carrying video data over a network. A packet 10 comprises a series of fields as follows: a video packet header 12 which contains general header information relevant to MPEG-4 processing, and two more fields which contain different types of compressed image data, motion vectors 14 and DC and AC DCT data 16.

Generally in MPEG-4, video images are dealt with by dividing a frame into macro-blocks of a given pixel size which are found to persist over a series of images, albeit with slight changes including movement over the image. Thus both an image movement vector and actual image data may be used at different stages to represent the various macro blocks. The image data is generally encoded in three stages, a first stage being discrete cosine transform (DCT), which causes progressively higher levels of detail to migrate towards one corner of the image. A quantization stage then leads to a certain reduction in the quantity of data and this is followed by a stage of Huffman, or variable length, encoding, to provide a high level of data compression. The compressed image data obtained is placed into fields in a series of packets for streaming. Generally in image data, as opposed to text, a certain amount of data loss can be tolerated without the effects being particularly noticeable to the viewer and thus lossy compression methods can be tolerated. However, the compressed data is sensitive to data loss. Reconstruction of the image from the compressed data requires that most of the compressed data be present although reconstruction success is unequally affected by different types of data. In the example of FIG. 1, the video packet header 12 is essential to correct reconstruction of the data, the motion vector data 14 is important but less critical than the header data 12 and the DCT information 14 is least critical of all. Thus, if the packets are being transmitted over a channel in which bandwidth is at a premium, then unequal levels of protection may be provided for the different types of data.

It is therefore desirable to provide packets such as packet 10 of FIG. 1, with a form of protection against channel data loss, distortion and erasure that allows for such unequal levels of protection of parts of the packet. Furthermore, it is desirable to provide a level of protection which allows for reconstruction of the image in the event of erasure of entire packets and even bursts of packets, in the event of their erasure by the channel.

Convolutional coding, and in particular recursive systematic convolutional coding, is a popular error correction scheme in communication systems, largely due to the compact and regular description of the code via a trellis diagram and the corresponding maximum likelihood decoding algorithm known as the Viterbi algorithm (see G. D. Forney, “The Viterbi algorithm,” Proc. IEEE, vol. 61, no. 3, pp. 268-278, March 1973, the contents of which are hereby incorporated by reference). An important advantage of convolutional coding is that it is easy to provide unequal coding levels as discussed above using the same convolution code by means of a technique known as puncturing, which will be described in more detail below.

Furthermore, the use of a systematic code, such as a systematic convolutional code, for error correction is of particular interest as it allows the parity check bits to be transmitted as a separate stream. This has the advantage of rendering the system backwards compatible with non-FEC capable hosts, so that receivers which cannot benefit from the FEC advantages can simply ignore the parity bits. On the other hand, in general, the free distance of systematic convolutional codes is lower than that of the equivalent (same number of states) non-systematic convolutional (NSC) code, consequently giving inferior performance. A recursive systematic convolutional (RSC) code combines the properties of the NSC and systematic codes, and in particular, its bit error rate (BER) performance is better than the equivalent NSC code at any signal to noise ratio for codes rates larger than ⅔.

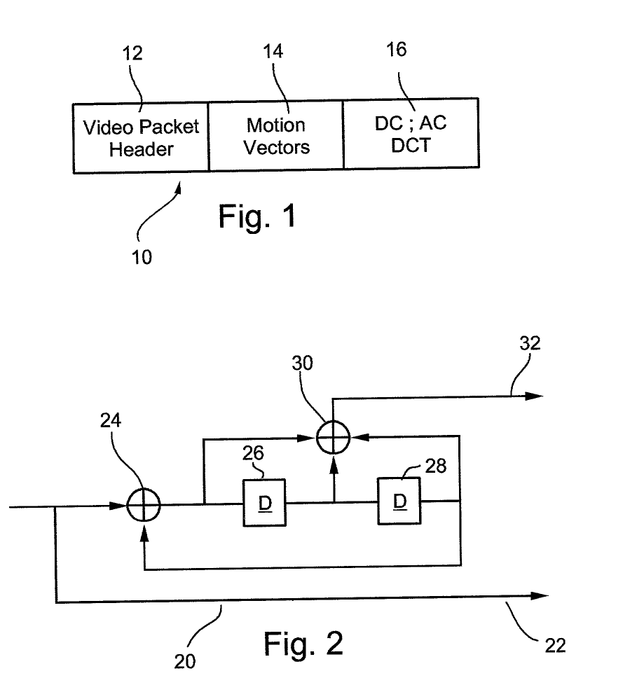

Reference is now made to FIG. 2, which shows an exemplary systematic recursive convolutional encoder. Encoder 20 is a binary rate ½ NSC encoder with m=2 memory elements, and comprises a first output 22 for direct output of unmodified content data (the systematic output). Content data is additionally fed to a first summator 24 where it is summed with its own output twice delayed by being passed through two delay gates 26 and 28 (the memory elements). A second summator 30 produces a sum of the current, the first delayed and the second delayed outputs of the first summator 24 as a second output 32 (the recursive output).

Generally, a binary rate RSC code is obtained from a NSC code by using a feedback loop and setting one of the two outputs equal to the input bit, for example as in the encoder 20 of FIG. 2. Considering the code generated by the encoder of FIG. 2, the code can be specified by two generator polynomials G′₁=1+D+D², G′₂=1+D², where D represents a delay element. An equivalent RSC code may be represented by the generator polynomials G₁=1, G₂=(1+D+D^{2)/(}1+D²).

As discussed above, unequal levels of encoding may be achieved using such an encoder by puncturing, meaning excluding certain outputs produced by the encoder. Thus for example, all the outputs may be used for the most critical parts of the data, giving maximal reconstructive ability, whereas the least critical parts of the data may use high levels of puncturing to remove most of the parity bits generated by the encoder. Puncturing may be implemented by using a puncture matrix which defines a perforation pattern. For example, for a puncture matrix

$$A = [ \begin{matrix}1 & 1 \\ 1 & 0\end{matrix} ] ,$$

every even parity check bit is punctured, resulting in a rate ⅔ code.

It will be appreciated that if A has zero elements in the first row, then the code ceases to be systematic, since the first row represents the bits of the unmodified data.

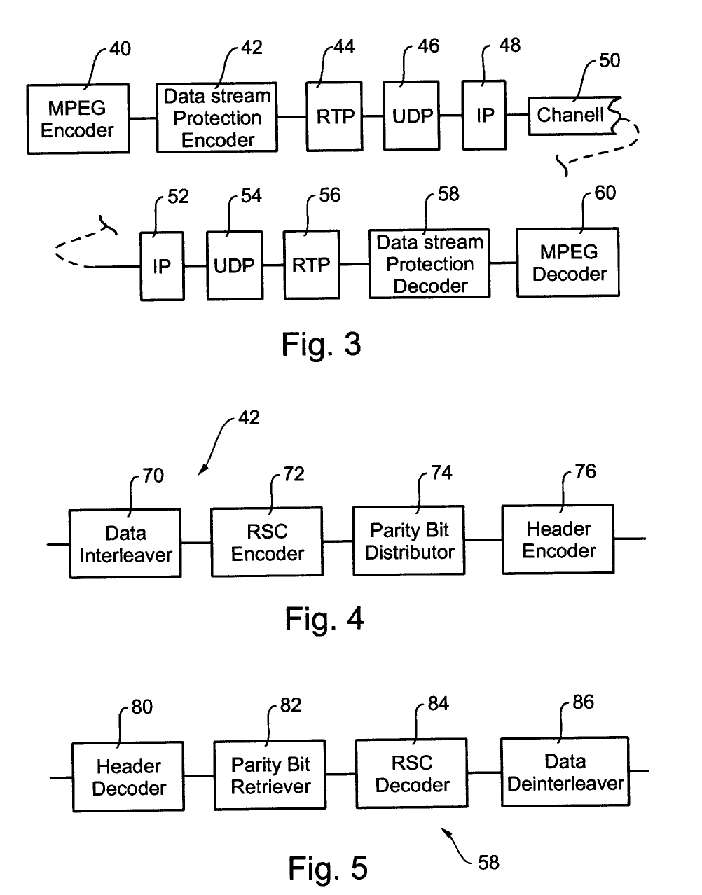

Reference is now made to FIG. 3, which is a simplified block diagram showing a system for managing data packet transfer according to a first embodiment of the present invention. An MPEG encoder 40 produces a stream of packets of the kind shown in FIG. 1, typically variable length packets, which stream is then processed by a datastream protection encoder 42. The data protection encoder 42 performs the function of decreasing the sensitivity of the compressed MPEG-4 data in the received data packets to data loss, distortion or erasure in the channel, as will be explained in greater detail below. The stream is then passed through RTP 44, UDP, 46 and IP 48 protocol layers for transfer along a channel 50. In the channel, the stream is subject to distortion, delay and erasure. It is noted that in the case of multimedia data needed for real time playing, delayed packets are in effect erased packets as they arrive too late.

At the far end of the channel 50, the stream passes through a reversed order of protocol layers, IP 52, UDP 54 and RTP 56, to a datastream protection decoder 58, whose function is complementary to that of the encoder 42 and which will be described in greater detail below. Finally the data packets are passed to an MPEG decoder 60 with channel errors repaired as far as possible.

Considering operation of the system in greater detail, let us take P={p₁, . . . pₖ} to stand for a set, or stream, of k media packets (bit streams), where each pi is obtained at the output of a media encoder, such as MPEG-4 encoder 40. Thus, each pi is a video packet containing an integer number of compressed macro blocks. The size of a compressed macro block is not fixed, but rather depends on the amount of information it carries and the particular compression algorithm being used by the media encoder 40. Consequently, the length of a video packet is not known in advance and can vary between predefined upper and lower limits. Preferably, l₁, . . . , lₖ denote the lengths of p₁, . . . , pₖ, respectively, such that lᵢ is a non-negative integer.

The set P is transmitted over a noisy channel 50. The channel may be a wireline or wireless network or any combination of wireless and wireline, and in particular may at least partially include a cellular network where bandwidth is at a premium. For example, the channel 50 might comprise the RTP/UDP/IP layers of the Internet (as shown), lower layers of the Universal Mobile Telecommunication System (UMTS), and a wireless fading channel in between the physical layers of the UMTS.

Generally, due to the nature of the channel 50, some of the transmitted packets may not arrive in time (or not arrive at all). In addition, some packets may be received partially corrupted, i.e., may contain errors. Denoting by P′ the set of received (and possibly partially corrupted) packets, an objective of the present embodiment is to enable reconstruction of the entire set P from P′. The reconstruction is based on interleaving and RSC encoding applied to the compressed data at the datastream protection encoder 42, as will be described in greater detail below. The RSC encoding, as will be described in greater detail below, preferably generates a set Q of parity check bits. To maintain compatibility with receivers that do not support FEC, the format of the compressed data itself is preferably not affected, i.e., the data is transmitted in a standard compliant (in the preferred embodiment, MPEG-4 compliant) manner (the systematic output of FIG. 2).

Reference is now made to FIG. 4 which is a simplified diagram showing the datastream protection encoder 42 in greater detail. The encoder 42 comprises a data interleaver 70, an RSC encoder 72, a parity bit distributor 74 and a header encoder 76.

The interleaver 70 preferably carries out interleaving only for the purpose of generating the set Q of parity bits. The data, itself is transmitted in a non-interleaved form. In addition, the parity check bits are transmitted separately or in an Internet packet header extension (in the preferred embodiment, RTP header extension). An advantage of the present embodiment is that the selection of any particular RSC code can be changed in real time to enable a judicious tradeoff between complexity and performance. In some of the embodiments the parameters of the selected RSC encoding scheme are preferably appended to the Q set and transmitted to the receiver. In an alternative embodiment the parameters are at least partially set according to reception conditions reported in a feedback path by the receiver, as will be described in greater detail in relation to FIG. 7 below.

Another preferred feature of the present embodiment is its ability, using puncturing as discussed above, to apply unequal error protection (UEP) RSC encoding to different fields of the data according to respective significance levels of the fields. Such a feature is particularly useful in audio/video applications, and enhances the overall performance of the system, as discussed above with respect to FIG. 1. For example, in MPEG-4 encoding the motion vectors are more significant for the reconstruction of the video frame at the receiver than are the DCT coefficients.

The encoding procedure is thus composed of the following four steps:

a) Data interleaving,

b) RSC coding,

c) Interleaving and apportionment of parity bits, and

d) Header encoding

As may be seen from FIG. 4, the data bits are interleaved prior to RSC encoding to prevent, in the event of packet loss, the occurrence of bursts of errors or erasures in the decoding procedure at the receiver. In order to achieve prevention of such bursts, the data interleaving procedure preferably satisfies a uniformity criterion as follows:

Uniformity means that the bits of each packet pᵢ are distributed in a uniform manner along the data interleaved bit stream. More specifically, if W denotes a window of length w through which a portion of the data interleaved stream may be viewed, then for any window W along the interleaved bit stream, pᵢ(W) denotes the number of bits belonging to pᵢ. The uniformity criterion requires that the relative proportion pᵢ(W)/w of bits belonging to each pᵢ is approximately equal to the proportion of lengths lᵢ/s, where

$$s = {\sum }_{i = 1}^{k} {l}_{i}$$

is the total number of data bits.

In a preferred embodiment of the present invention there is provided an algorithm for performing data interleaving according to the aforementioned uniformity criterion. The algorithm selects at each time unit a packet from which the current bit is drawn, and appends the selected bit to the interleaved bit stream. If denoting by nᵢ the number of bits already selected from packet pᵢ. then

$$n = {\sum }_{i = 1}^{k} {n}_{i} ,$$

i.e., n is the total number of bits selected thus far by the algorithm. The packet pᵢ, from which the current bit is drawn, is selected as the packet that minimizes the following expression:

$$\frac{{n}_{i} + 1}{n + 1} - \frac{{l}_{i}}{s} .$$

The algorithm continues as long as n is less than s. If the selected packet is one in which nᵢ is already equal to lᵢ, then a zero bit is inserted instead of a data bit. Note that if all packets have equal lengths, the algorithm is reduced to iteratively passing over all the packets in a circular manner. In the case of unequal originating packets the algorithm adds the greater number of check bits to the smaller packets, giving the advantage that overall reconstructive ability is more evenly distributed around the packets. Thus the loss of any given packet is less likely to have a disproportionately high influence on data reconstruction. Those packets having fewer data bits will have more parity bits and vice versa.

UEP RSC encoding is next preferably applied to the data interleaved bit stream, by the RSC encoder 72. The parameters of the RSC code are:

a feed-forward polynomial,

a feedback polynomial, and

a puncturing pattern.

The puncturing pattern, as discussed above, serves to change the error correction capability of the RSC code according to the priority of the data in the respective field. For example, high-rate error correction coding (i.e., many parity check bits being punctured) may be applied to low-priority data such as high-frequency DCT coefficients, whereas high-priority data such as addresses of blocks, motion vectors, and low-frequency DCT coefficients may be more efficiently protected by applying a sparse puncturing pattern to the RSC coded data. In the following, two examples are given in which rate ½ RSC codes, obtained by computer search, give effective performance with a puncturing pattern

$$A = [ \begin{matrix}1 & 1 \\ 1 & 0\end{matrix} ] .$$

It will, of course, be appreciated that the puncturing changes the rate of the codes to ⅔.

The first exemplary RSC code is a 4-state code with generator polynomials G₁=1 and G₂(1+D)/(1+D+D²). For k=7 and l₁=l₂= . . . =l₇ such a code can recover any combination of 2 out of 7 lost packets. The second exemplary RSC code is a 64-state code with generator polynomials G₁=1 and G₂=(1+D+D⁴+D⁵+D⁶)/(1+D+D²+D⁴+D⁵). For k=10 and l₁=l₂= . . . =l₁₀ the second code can recover any combination of 3 out of 10 lost packets.

The RSC encoding and puncturing procedure, of either example, generates a set Q of parity check bits. The parameters of the RSC encoding scheme are then transmitted to the receiver along with the set Q of parity check bits. As the parameters are explicitly transmitted, any changes therein can be followed at the receiver and thus the parameters may be changed at the encoder in real-time without any prior notification to the receiver.

In UEP encoding, as discussed above, the puncturing pattern is advantageously changed along the interleaved data bit stream according to the importance of the data protected. Thus, the positions along the stream where the puncturing pattern changes are made are preferably transmitted to the receiver.

The RSC encoder 72 is followed by the parity bit distributor 74, whose task is to interleave and apportion the parity bit set Q (after puncturing) before transmission so as to apply the uniformity criterion and thereby to prevent the occurrence of burst errors and erasures at the receiver. The interleaved set Q is preferably apportioned into k portions q₁, . . . , qₖ of lengths m₁, . . . , mₖ, respectively, where each qᵢ is transmitted in the same Internet packet containing pᵢ. The uniformity criterion preferably used in the interleaving and apportionment procedure requires that lᵢ+mᵢ will be approximately the same for all i. As discussed on outline above, in case an Internet packet is lost, the number of missing bits will be approximately constant irrespective of the index of the lost pair {pᵢ, qᵢ}. In order to satisfy such a constraint, a procedure known as a “water filling” procedure may be employed to append parity bits to the data packets.

The uniformity criterion preferably also requires that the missing lᵢ+mᵢ bits are distributed in a uniform manner along the received and de-interleaved bit stream at the input to the UEP RSC decoder (decoder 84 in FIG. 5). Stated otherwise, for any window of length w through which a portion of the de-interleaved bit stream may be viewed, the number of missing bits, in case of one lost packet, will be approximately w/k. The preferred algorithm for interleaving and apportioning Q in parity bit distributor 74 is similar to the algorithm used for interleaving the data bits in data interleaver 70. Preferably, the bits of Q are initially arranged according to the order of their generation by the RSC code in encoder 72. The algorithm then selects, at each time unit, a parity set qᵢ into which a selected next bit of Q is to be placed. Denoting by zᵢ the number of bits already in set qᵢ:

$$z = {\sum }_{i = 1}^{k} {z}_{i} ,$$

that is to say z is the total number of bits distributed thus far by the algorithm. The set qᵢ in which the current bit is placed, is the set that minimizes the following expression

$$\frac{{z}_{i} + 1}{z + 1} - \frac{{m}_{i}}{r} ,$$

where r is the size of Q in bits. Note that this algorithm does not guarantee uniform distribution of parity bits between packets in case one of the data packets is too long, i.e., if one of the lᵢ is greater than (s+r)/k.

The parity bit distributor 74 is followed by the header encoder 76 for performing a final step in the encoding procedure, namely to append a header containing the encoding parameters to the parity bits. The information encoded in the header typically includes:

the lengths {m₁, . . . , mₖ} of the parity bits,

the parameters of the specific RSC code,

the UEP puncturing pattern, and

the tail of the recursive code.

It is appreciated that there is no need to explicitly encode the length of the data packets since this information can be deduced from the remaining parameters. The header is encoded with a fixed predetermined error correction code, and the encoded header bits are then preferably distributed among the transmitted Internet packets. The encoding of the header should be strong enough to allow perfect reconstruction of the header under conditions of severe packet loss.

In an alternative embodiment, in order to reduce the length of the header, a small number of legitimate combinations of header parameters could be determined in advance. In this case, only the index of the selected combination need be transmitted as header information.

Reference is now made to FIG. 5, which a simplified block diagram showing in more detail the datastream protection decoder 58 at the receiving end of the channel 50 in FIG. 3. The datastream protection decoder 58 is designed to receive signals that have been encoded using the datastream protection encoder 42 and preferably comprises similar sub-units thereto but arranged in the reverse order. A header decoder 80 is preferably the first unit in the receiver, followed by a parity bit retriever 82, an RSC decoder 84 and a data deinterleaver 86.

Preferably, decoding is performed on a subset of the transmitted packets as follows. First, encoded header bits are collected from the received packets (i.e., those that have survived transmission through the channel 50). The collected header bits are preferably decoded at the header decoder 80 to recover the header parameters. The recovered header parameters are then used by the parity bit retriever 82 to de-interleave the received set of parity bits and to identify the positions of any erasures that may have occurred. For the purpose of decoding, erasure bits are associated with a zero metric. The header parameters may be used to construct a trellis diagram corresponding to the UEP RSC code that was employed to encode the data. A conventional Viterbi decoding procedure may then be used to decode the received information and reconstruct the interleaved data. The decoding procedure preferably comprises a search through the trellis for the UEP RSC codeword (i.e., bit stream) with minimum Hamming distance form the received sequence of data and parity bits, which, having been found is selected as the most probable bit stream. Then, the selected bit stream is passed to the data deinterleaver 86 for the data to be de-interleaved according to the data de-interleaving scheme (the complement of the data interleaving scheme used by data interleaver 70) and separated into data packets.

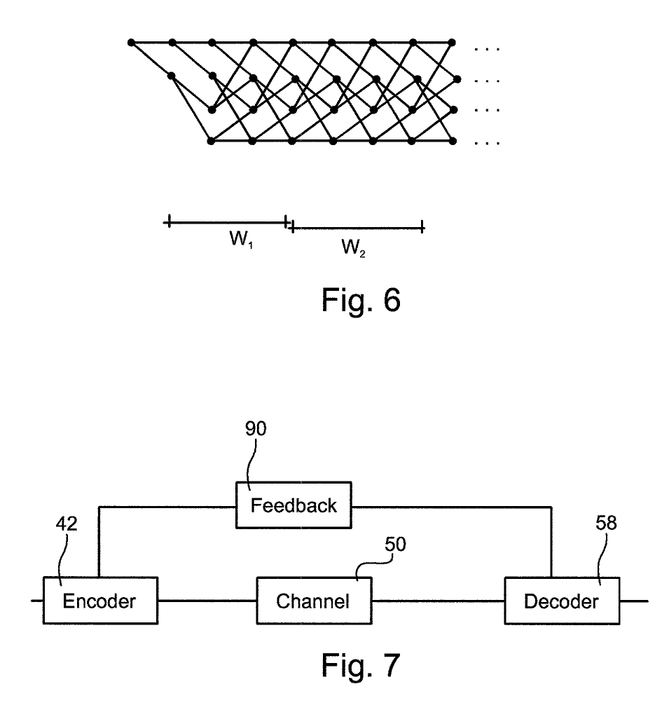

Reference is now made to FIG. 6, which shows eight steps in a simplified trellis diagram. The trellis diagram comprises a series of paths covering all possible message combinations. In normal circumstances, a regular trellis decoding algorithm yields a single surviving path, the path having a minimum Euclidian distance or Hamming weight to the received bit stream. However, if the channel is especially noisy then several paths may be equally probable, and an ability to choose efficiently between paths having equal probability levels extends the ability of the system to deal with channel noise and erasure. Generally, many surviving paths can be rejected because they contain illegal combinations, that is to say combinations of bits that do not appear in a codebook being used. As will be appreciated, in conditions of high channel distortion, the number of surviving paths may grow very large very quickly. Windows, such as those indicated as W1 and W2, are thus used to examine the surviving paths, as will be explained in more detail below.

When the number of lost packets exceeds the error correction capability of the RSC code, the standard Viterbi decoder, even if employed as part of the above-described receiver, will most likely fail to decode to the correct bit stream, that is to say there is a good chance that more than one path will share a minimum Hamming distance, and the standard decoder will be at a loss to choose therebetween. The embodiment of FIG. 6 thus extends the performance of a system that uses trellis coding as a means of FEC of media packets transmitted through a noisy channel. A trellis code is defined as any error correcting code that has a trellis representation, and includes convolutional codes, RSC codes, and even block codes. The present embodiment is useful under conditions of severe packet loss and preferably employs a residual redundancy in the compressed data to be able to select the correct bit stream among a relatively small number of candidate codewords that constitute a sub-trellis of the trellis diagram (in the preferred embodiment the trellis describes an RSC code, although the skilled person will appreciate that the embodiment is applicable to any code having a trellis representation). In MPEG, particularly MPEG-4, encoding, the multiplexed video bit stream generally comprises variable length code (VLC) words. The video bit stream is not free of redundancy, such that violations of syntactic or semantic constraints will usually occur quickly after a loss of synchronization (see, e.g., C. Chen, “Error detection and concealment with an unsupervised MPEG2 video decoder,” J. Visual Commun. Image Representation, vol. 6, no. 3, pp. 265-278, September 1995, and J. W. Park, J. W. Kim, and S. U. Lee, “DCT coefficients recovery-based error concealment technique and its application to the MPEG-2 bit stream,” IEEE Trans. Circuits Syst. Video Technol., vol. 7, pp. 845-854, December 1997, the contents of which are hereby incorporated by reference). For example, the decoder may not find a matching VLC word in the code table (a syntax violation) or may determine that the decoded motion vectors, DCT coefficients, or quantizer step sizes exceed their permissible range (semantic violations). Additionally, an accumulated run that is used to place DCT coefficients into an 8×8 block may exceed 64, or the number of MB's (macro-blocks) in a group of blocks (GOB) may be too small or too large. Especially for severe errors, the detection of errors can be further supported by localizing visual artifacts that are unlikely to appear in natural video signals.

Another source of reliability information on candidate bit streams useful for eliminating paths within the window may be obtained from receiver provided channel state information, or from a soft output Viterbi algorithm (SOVA) that may be used for decoding of convolutional codes (see J. Hagenauer and P. Hoher, “A Viterbi algorithm with soft-decision output and its applications,” in Proc. IEEE Global Telecommunications Conf. (GLOBECOM), Dallas, Tex., November 1989, pp. 47.1.147.1.7, the contents of which are hereby incorporated by reference).

Recently, more advanced techniques for improved resynchronization have been developed in the context of MPEG-4. Among several error resilience tools, data partitioning has been shown to be effective (see R. Talluri, “Error-resilient video coding in the MPEG-4 standard,” IEEE Commun. Mag., vol. 36, pp. 112-119, June 1998—the contents of which are hereby incorporated by reference. In particular data partitioning may be combined with reversible VLC (RVLC), thus allowing bit streams to be decoded in either the forward or reverse direction. In such a case, the number of symbols that have to be discarded can be reduced significantly. Because RVLC's can be matched well to the statistics of image and video data, only a small penalty in coding efficiency is incurred (see, e.g., J. Wen and J. D. Villasenor, “A class of reversible variable length codes for robust image and video coding,” in Proc. 1997 IEEE Int. Conf. Image Processing (ICIP), vol. 2, Santa Barbara, Calif., October 1997, pp. 65-68, and also J. Wen and J. D. Villasenor, “Reversible variable length codes for efficient and robust image and video coding,” in Proc. IEEE Data Compression Conf. (DCC), March 1998, Snowbird, Utah, pp. 471-480, the contents of which are hereby incorporated by reference).

In the present embodiment, a set of data packets (bit stream), which has been encoded by a trellis code at the transmitter is received at the receiver end. The stream is then decoded at the datastream protection decoder 58 using a search through the trellis for the most likely bit stream. If the number of lost packets does not exceed the error correction capability of the trellis code then the conventional Viterbi algorithm may normally be expected to yield a single data path as a most likely candidate for the error-free bit stream. If, however, too many data packets have been lost or corrupted, then the search through the trellis for the most likely bit stream may result in more than one candidate data path, meaning several data paths each having the same likelihood of being the correct bit stream, i.e., being at the same Hamming distance from the received bit stream.

In conventional trellis decoding, if we denote by S the set of the equally likely candidates, then a preferred way to identify the set S is by applying a minimum distance decoder (such as the Viterbi algorithm) to the trellis in the following manner: At each trellis node a comparison is made between the accumulated metrics (accumulated hamming distances) of the paths entering the node. The most likely path to the node is retained and the remaining paths are discarded. If, however, there is a tie, i.e., there are L paths with the same likelihood measure, then all those L paths are retained while the other paths are discarded. This process is repeated for each trellis node and each section until the end of the trellis is reached. At the end of the process, the surviving paths through the trellis constitute a sub-trellis which represents the set S of candidate bit streams.

Generally, the set S of surviving bit streams would be too large to process by the residual redundancy methods described above. Thus in the present embodiment there is provided a low-complexity method to eliminate candidate bit streams and reduce S into a single candidate. A sliding window B of width b is used, and a portion of the sub-trellis may be viewed and processed through the window. In FIG. 6, the window is shown with a width b of three nodes, purely for the purpose of simplicity of illustration. In practice it will generally be larger. The objective is to eliminate paths that are unlikely to be correct. Hence the parameter b should be taken to be large enough to enable meaningful processing of the paths through B, i.e., to enable examination of the elimination criteria described below. At the beginning of the procedure, the window W is positioned at the end of the sub-trellis and the paths through the window W are examined. A path through W is eliminated if it violates a syntactic constraint (e.g., the decoder cannot find a matching VLC word in the code table), a semantic constraint (e.g., the DCT coefficients exceed their permitted range), or some other likelihood criteria as follows:

A decoded bit stream is considered not likely if it includes visual artifacts that are unlikely to appear in natural video images.

A bit stream is not likely if the corresponding DCT coefficient distribution is not likely. Lam et al (Lam, E. Y. and Goodman, J. W., “A mathematical analysis of the DCT coefficient distributions for images” IEEE Trans. Image Processing, Vol. 9, No.10, October 2000, the contents of which are hereby incorporated by reference) provide a mathematical analysis of the DCT coefficient distributions in natural images. The correspondence between their model and the distribution of the decoded DCT coefficients can be used as a measure of likelihood.

A macroblock is not likely if it has low correlation with its neighboring macroblocks. The correlation can be in the spatial and/or frequency and/or temporal domains. Many appropriate correlation measures have been developed for the purpose of passive error concealment (see Section V in Wang, Y. and Zhu, Q. -F., “Error control and concealment for video communication: A review” Proc. IEEE Vol. 86, No. 5, May 1998, the contents of which are hereby incorporated by reference). For example, using temporal correlation, a macroblock that is very different from the motion-compensated corresponding macroblock in the previous frame is classified as not likely. Using spatial correlation, a macroblock whose boundaries do not agree with the boundary pixels of neighboring macroblocks in the same frame is classified as not likely.

The processing of the sub-trellis by the sliding window W preferably results in a single survivor path through W. The paths that do not survive the processing by the window W are eliminated from the sub-trellis together with all their “descendents”, i.e., all the paths through the remainder of the sub-trellis that are connected to the eliminated paths. The next step is thus to slide the window b positions towards the beginning of the sub-trellis (window W2 in FIG. 6) and repeat the elimination process. The procedure repeats until the beginning of the sub-trellis is reached. A simple traceback procedure now yields the single surviving bit stream. If at some stage the elimination process cannot be concluded successfully with a single survivor, then a decoding failure is declared. Alternatively, b may be increased to allow a more reliable (and more complex) processing using a larger window.

Reference is now made to FIG. 7, which is a simplified block diagram of a version of the device of FIG. 3 additionally having a feedback loop. Parts that are identical to those shown above are given the same reference numerals and are not referred to again except as necessary for an understanding of the present embodiment. In the embodiment, a datastream protection encoder 42 and a datastream protection decoder are connected via a channel 50 as before, but in addition the channel furnishes a return route which serves as a feedback link 90. The feedback loop allows the decoder 58 to report back to the encoder so that the encoder is able to use real time data from the decoder to set its encoding parameters.

Generally, if a reverse, or feedback, channel from the decoder 58 to the encoder 42 is available, better performance can be achieved since the encoder 42 and decoder 58 are thereby enabled to cooperate in the process of error correction and concealment. The feedback channel 90 may be used to indicate received noise levels and/or which parts of the bit stream were received intact and/or which parts of the video signal could not be decoded and had to be concealed. Depending on the desired error behavior, negative acknowledgment (NACK) or positive acknowledgment (ACK) messages can be sent. Typically, an ACK or NACK may refer to a series of macroblocks or an entire group of blocks (GOB). NACK's require a lower bit rate than ACK's, since they are only sent when errors actually occur, while ACK's have to be sent continuously. In either case, the requirements on the bit rate are very modest compared to the video bit rate of the forward channel.

The feedback message is usually not part of the standard video syntax but transmitted in a layer of the protocol stack which allows for control information to be exchanged. A survey of techniques for processing of acknowledgment information obtained from a feedback channel in general appears in a paper by Girod et al (B. Girod and N. F. Arber, “Feedback-Based Error Control for Mobile Video Transmission,” Proc. IEEE, Vol. 87, No. 10, October 1999, the contents of which are hereby incorporated by reference.)

In the embodiment of FIG. 7, a system that performs adaptive error correction and concealment in media communications is based on feedback information from the decoder, as described above. Preferably, the embodiment uses the UEP RSC code as described above for error correction of variable-length media packets, where the particular RSC code, the puncturing pattern, the boundaries of the different priority fields, and the data and parity interleaving schemes can be adapted in real time according to control information sent from the decoder 58. Thus, if the decoder indicates that data is being successfully decoded with ease, the level of encoding at the encoder 42 may be reduced. On the other hand, if the decoder 58 indicates that it is having difficulties in decoding, then the level of encoding may be increased and thus there is provided a dynamic response to the conditions of the channel. The feedback signal may refer to encoding in general. In an embodiment in which unequal encoding is used, the feedback may be specific to the individual data fields. The embodiment thus preferably offers optimal utilization of bandwidth by allowing real-time adaptivity to channel conditions, real-time controlled unequal error protection, efficient exploitation of the processing power at the transmitter and receiver, and real-time adaptivity to variations in packet size.

In accordance with embodiments of the present invention there is thus provided a system for efficient processing of compressed multimedia data for a real time data stream which makes the compressed data less sensitive to distortions, delays and erasure in the channel.

It is appreciated that certain features of the invention, which are, for clarity, described in the context of separate embodiments, may also be provided in combination in a single embodiment Conversely, various features of the invention which are, for brevity, described in the context of a single embodiment, may also be provided separately or in any suitable subcombination.

It will be appreciated by persons skilled in the art that the present invention is not limited to what has been particularly shown and described hereinabove. Rather the scope of the present invention is defined by the appended claims and includes both combinations and subcombinations of the various features described hereinabove as well as variations and modifications thereof which would occur to persons skilled in the art upon reading the foregoing description.

1. A decoding device for receiving a data stream from a data source over a noisy channel, the data being arranged in variable length packets using unequal encoding levels for different parts of the data stream, the decoder having a feedback transmitter for sending feedback data via a feedback channel to said data source to indicate a level of quality of data receipt at said decoder, thereby to provide dynamic adaptation to conditions in said channel.

2. A decoding device according to claim 1, operable to decode data encoded using RSC encoding.

3. A decoding device according to claim 1, the data stream comprising data bits in a utilization order and interleaved parity bits, in a succession of data packets, the device comprising:
a data receiver for receiving said data stream,
a data receiver for deinterleaving said data bits,
a parity bit retriever for retrieving and deinterleaving said parity bits from said data stream, and
a decoder for decoding said data bits with said deinterleaved parity bits, thereby to reconstruct data erased by said channel.

4. A decoding device according to claim 1, wherein said data packets comprise a plurality of fields of differing importance and wherein said data stream comprises unequal levels of error protection encoding to said fields, said feedback transmitter being operable to signal to said data source to increase said unequal levels of protection in the event of an increase in channel noise and to decrease said unequal levels of protection in the event of a decrease in said channel noise.

5. A decoding device according to claim 4, wherein said data packets comprise video data compressed using a transform combined with motion vectors of identified macroblocks.

6. A decoding device according to claim 5, wherein parameters of at least one of said unequal error protection encoding levels and said puncture matrix are obtained from a packet header.

7. A decoding device according to claim 6, wherein said header comprises an index defining a combination of unequal error protection encoding level and a puncture matrix in said packet header.

8. An encoding and transmitting device for encoding a data stream and transmitting said data stream over a noisy channel to a receiver device, the encoder having:
at least one encoder for encoding said data,
a packetizer for arranging the encoded data into variable length encoded packets using unequal encoding levels for different parts of the packet,
a feedback receiver for receiving feedback data via a feedback channel from said receiving device to indicate a level of quality of data receipt at said receiving device, and
an adapter for utilizing said feedback data to modify parameters used in said encoder, thereby to provide adaptive error correction and concealment in a data stream transferred over said channel.

9. An encoding and transmitting device according to claim 8, wherein said data packets comprise a plurality of fields of differing importance and wherein said encoder is operable to apply unequal levels of error protection encoding to said fields.

10. An encoding and transmitting device according to claim 8, said encoder being operable to apply said unequal levels of error protection encoding via a puncture matrix.

11. An encoding and transmitting device according to claim 8, said encoder being operable to produce parity bits with a recursive systematic convolutional encoding process using parameters selectable in response to said feedback data.

12. An encoding and transmitting device according to claim 11, wherein said recursive systematic convolutional encoding process is defined by
G=(1+D)/(1+D+D²),
where D indicates a once delayed prior input and D² indicates a twice delayed prior input.

13. An encoding and transmitting device according to claim 11, wherein said recursive systematic convolutional encoding process is defined by
G=(1+D+D⁴+D⁵+D⁶)/(1+D+D²+D+D⁵),
where D indicates a once delayed prior input, D² indicates a twice delayed prior input, D⁴ indicates a four times delayed prior input, D⁵ indicates a five times delayed prior input, and D⁶ indicates a six times delayed prior input.

14. An encoding and transmitting device according to claim 13, wherein said encoder is operable to apply said unequal levels of error protection encoding via a puncture matrix, said puncture matrix being selectable according to said feedback data.

15. An encoding and transmitting device according to claim 14, wherein said data packets comprise a plurality of fields of differing importance and wherein said encoder is operable to apply unequal levels of error protection encoding to said fields, according to parameters selectable according in accordance with said feedback data.

16. An encoding and transmitting device according to claim 8, wherein said encoder further comprises a data interleaver, being operable to interleave said data in accordance with a uniformity criterion and wherein said uniformity criterion is selected such as to allow reconstruction of erased data packets from surviving data packets, whenever said erased data packets do not exceed a predetermined proportion of said surviving data packets.

17. An encoding and transmitting device according to claim 16, wherein said uniformity criterion is such that for any window over a length w of said interleaved data, the proportion of data bits from any given packet remains substantially constant.

18. An encoding and transmitting device according to claim 13, wherein parameters of at least one of said unequal error protection encoding levels and said puncture matrix is included in a packet header and are variable in accordance with said feedback data.

19. An encoding and transmitting device according to claim 18, selectably operable to use any selected one of only a predetermined set of combinations of puncture matrices and differential encoding levels, which selection is influenced by said feedback data and which is operable to include an index of said selected combination in a packet header.

20. An encoding and transmitting device according to claim 8, comprising
a plurality of encoders each for encoding using different encoding parameters, and
an encoder selector for selecting one of said plurality of encoders based on said feedback data.

21. A system for streaming data and corresponding protective parity bits in packets over a channel, the system comprising
a recursive systematic convolutional encoder at a sending end for producing said corresponding protective parity bits,
a recursive systematic convolutional decoder at a receiving end for reconstructing data lost in the channel, and
a feedback channel between said sending end and said receiving end for allowing encoding parameters at said sending end to be modified by receiving conditions at said receiving end.

22. A system according to claim 21, wherein said data packets comprise a plurality of fields of differing importance and wherein said encoder is operable to apply unequal levels of error protection encoding to said fields using parameters variable in accordance with feedback from said feedback channel.

23. A system according to claim 21, operable to apply said unequal levels of error protection encoding via a puncture matrix, and wherein said puncture matrix is variable in accordance with feedback from said feedback channel.

24. A system according to claim 22, wherein parameters of at least one of said unequal error protection encoding levels and said puncture matrix are variable in accordance with feedback from said feedback channel and are included in a packet header.

25. A system according to claim 22, wherein said encoder is operable to use any selected one of only a predetermined set of combinations of puncture matrices and unequal error protection encoding levels, said selection being at least partially dependent on feedback from said feedback channel and which encoder is operable to include an index of said selected combination in a packet header.

26. A system according to claim 21, wherein said channel includes a cellular connection.

27. A system according to claim 21, wherein said data comprises compressed video.

28. A system according to claim 21, wherein said compressed video comprises motion vector portions and transformed portions.

29. A method of transferring compressed multimedia data arranged into fields of varying importance over a channel liable to erasure in variable length packets, the method comprising:
inserting said data into said packets,
interleaving said data using a uniformity criterion,
generating parity bits using a recursive systematic convolutional code from said interleaved data according to parameters,
distributing said parity bits across said packets amongst said data,
transferring said packets over said channel,
reconstructing said compressed multimedia data at a receiver,
feeding back receipt conditions at said receiver back across said channel, and
modifying said parameters in accordance with said feedback, thereby to dynamically adapt encoding of said data stream to said channel conditions.
